(19) United States
(12) Patent Application Publication
(10) Pub. No.: US 2024/0302446 A1
(43) Pub. Date: Sep. 12, 2024

(54) ENERGY STORAGE SYSTEMS

(71) Applicant: Enphase Energy, Inc., Petaluma, CA (US)

(72) Inventor: Blake Richard LUNDSTROM, Lakewood, CO (US)

(21) Appl. No.: 18/596,821

(22) Filed: Mar. 6, 2024

Related U.S. Application Data
(60) Provisional application No. 63/450,499, filed on Mar. 7, 2023.

(51) Int. Cl. G01R 31/389; G01R 31/36; G01R 31/3842

(52) U.S. Cl. CPC G01R 31/389; G01R 31/3648; G01R 31/3842

(57) ABSTRACT

An energy storage system is provided and comprises a battery management unit; a controller configured to start an idle condition timer, measure a voltage of a battery cell of a battery connected to the battery management unit while the battery is idle, after the idle condition timer has expired, start a steady condition timer, measure the voltage of the battery cell while the battery is on, after the steady condition timer has expired, calculate a total resistance of the battery cell, and calculate an open circuit voltage of the battery cell using the total resistance.

### CROSS-REFERENCE TO RELATED APPLICATIONS

The present application claims the benefit of and priority to U.S. Provisional Application Ser. No. 63/450,499, filed on Mar. 7, 2023, the entire contents of which is incorporated herein by reference.

### BACKGROUND

### 1. Field of the Disclosure

Embodiments of the present disclosure generally relate to energy storage systems and, for example, to energy storage systems that use online estimation of battery cell resistance and open circuit voltage for cell balancing.

### 2. Description of the Related Art

Conventional energy storage systems configured for use with energy management systems are known. The energy storage systems (e.g., a battery system), typically, comprise one or more battery cells, e.g., a lithium-ion battery system, which can comprise one or more series connected battery cells that form a battery pack. The battery system requires monitoring the battery cells for health and implementing cell balancing control. Traditional low-cost approaches for battery cell balancing control can utilize a passive balancing circuit connected to each battery cell (or group of parallel battery cells) in a battery pack and turn on the passive balancing circuit for select battery cells to remove energy from the battery cells until all battery cells in the battery pack have equivalent energy levels. The battery cell balancing algorithms are configured to estimate an energy in each battery cell to determine which battery cell balancing circuits to turn on. For example, one common industry approach is to estimate battery cell energy using a lookup table based on open circuit voltage (V_{oc}). Other approaches can use both V_{oc} and cell current (I_{cell}) along with a model and/or coulomb counter. Thus, integral to most approaches is a good estimate of V_{oc}.

Many traditional approaches for battery cell balancing perform battery cell balancing while the battery is idle, thus making measurements of V_{oc} easier to obtain. Only performing balancing while the battery is idle, however, may not be adequate to meet a desired battery cell balancing criteria if the battery system does not have many long idle periods, e.g., where balancing control circuitry is powered on, which can be especially true for portable battery products and for fixed-installation residential battery systems where the battery pack is actively used for significant periods of the day. In such scenarios, approaches for continuous battery cell balancing, in which battery cell balancing is applied even while the battery pack is not idle, are needed. Continuous battery cell balancing requires that battery cell energy and, therefore, commonly V_{oc} be estimated during active battery pack operation.

Most battery management units/systems (BMU) measure battery pack level current (e.g., I_{load}), the terminal voltage of each battery cell (e.g., Vₜᵢ), and temperature readings from the battery pack. Thus, battery cell energy and V_{oc}, must be estimated using I_{load} and Vₜᵢ measurements. One common approach is to use an extended Kalman filter (EKF) that estimates a full internal state of the battery pack using a state space model of the battery cell and the I_{load} and Vₜᵢ measurements as inputs. Such an approach, however, requires tuning and can be computationally complex and is, therefore, often applied only at a battery pack level and is not particularly useful for battery cell level energy estimation. Another common model-based approach is auto regressive exogenous (ARX) modeling, which works by minimizing a difference between estimated voltage of a model and a measured terminal voltage. However, as with the EKF approach, the ARX approach also has higher computational complexity and may not be feasible for efficient, cost-effective estimation of battery cell level V_{oc} and energy.

In view of the foregoing, the inventors provide herein improved energy storage systems that use online estimation of battery cell resistance and open circuit voltage for cell balancing.

### SUMMARY

In accordance with some aspects of the present disclosure, an energy storage system comprises a battery management unit and a controller configured to start an idle condition timer, measure a voltage of a battery cell of a battery connected to the battery management unit while the battery is idle, after the idle condition timer has expired, start a steady condition timer, measure the voltage of the battery cell while the battery is on, after the steady condition timer has expired, calculate a total resistance of the battery cell, and calculate an open circuit voltage of the battery cell using the total resistance.

In accordance with some aspects of the present disclosure, a method for Rₜₒₜₐₗ estimation that can be used for battery cell balancing, state-of-charge (SOC), state-of-health (SOH), and/or health prediction comprises starting an idle condition timer, measuring a voltage of a battery cell of a battery while the battery is idle, after the idle condition timer has expired, starting a steady condition timer; measuring the voltage of the battery cell while the battery is on, after the steady condition timer has expired, calculating a total resistance of the battery cell; and calculating an open circuit voltage of the battery cell using the total resistance.

In accordance with some aspects of the present disclosure, a non-transitory computer readable storage medium has instructions stored thereon that when executed by a processor perform a method Rₜₒₜₐₗ estimation that can be used for battery cell balancing, state-of-charge (SOC), state-of-health (SOH), and/or health prediction. The method comprises starting an idle condition timer; measuring a voltage of a battery cell of a battery while the battery is idle, after the idle condition timer has expired, starting a steady condition timer; measuring the voltage of the battery cell while the battery is on, after the steady condition timer has expired, calculating a total resistance of the battery cell, and calculating an open circuit voltage of the battery cell using the total resistance.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a block diagram of an AC battery system configured for use with the system of FIG. 1, in accordance with at least some embodiments of the present disclosure;

FIG. 3 is a schematic diagram of an equivalent circuit model of a single battery cell, in accordance with at least some embodiments of the present disclosure;

FIG. 4 is a schematic diagram of an equivalent circuit model of multiple cells connected in series to form a battery pack, in accordance with at least some embodiments of the present disclosure;

FIG. 5 is flowchart of an Rₜₒₜₐₗ estimation method, in accordance with at least some embodiments of the present disclosure; and

FIG. 6 is a flowchart of a method for continuous battery cell balancing, in accordance with at least some embodiments of the present disclosure.

### DETAILED DESCRIPTION

The inventor discloses herein energy storage systems that use online estimation of battery cell resistance and open circuit voltage for one or more applications. For example, in at least some embodiments, the methods and apparatus described herein can be used for battery cell balancing, state-of-charge (SOC), state-of-health (SOH), health prediction, etc. For example, an energy storage system includes a battery management unit and a controller configured to start an idle condition timer, measure a voltage of a battery cell of a battery connected to the management unit while the battery is idle, after the idle condition timer has expired, start a steady condition timer, measure a voltage of the battery cell while the battery is on, after the steady condition timer has expired, calculate a total resistance of the battery cell, and calculate an open circuit voltage of the battery cell using the total resistance. The methods and apparatus disclosed herein provide a relatively low computational complexity approach for estimating battery cell resistance, open circuit voltage, more effective battery cell balancing actions, state-of-charge (SOC), state-of-health (SOH), health prediction, etc., for every battery cell in a battery pack that will ultimately result in longer battery life and contribute to safer battery operation.

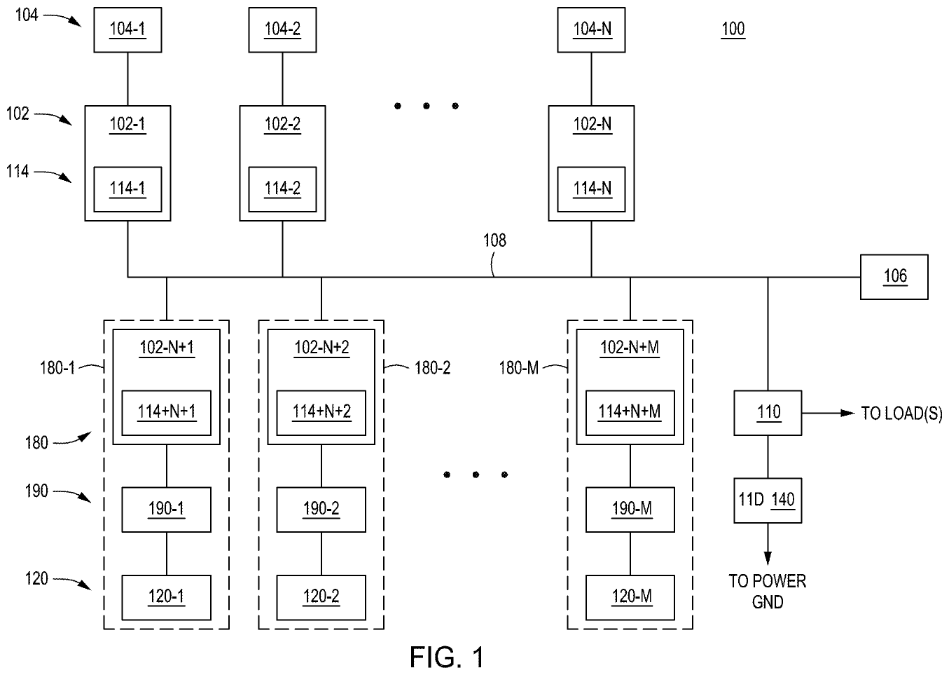

FIG. 1 is a block diagram of a system 100 (energy management system) for power conversion using one or more embodiments of the present disclosure. This diagram only portrays one variation of the myriad of possible system configurations and devices that may utilize the present disclosure.

The system 100 is a microgrid that can operate in both an islanded state and in a grid-connected state (i.e., when connected to another power grid (such as one or more other microgrids and/or a commercial power grid). The system 100 can comprise one or more power converters. In at least some embodiments, the system 100 comprises a plurality of power converters 102-1, 102-2, . . . 102-N, 102-N+1, and 102-N+M collectively referred to as power converters 102 (which also may be called power conditioners); a plurality of DC power sources 104-1, 104-2, . . . 104-N, collectively referred to as power sources 104; a plurality of energy storage devices/delivery devices 120-1, 120-2, . . . 120-M collectively referred to as energy storage/delivery devices 120; a system controller 106; a plurality of BMUs 190-1, 190-2, . . . 190-M (battery management units) collectively referred to as BMUs 190; a system controller 106; a bus 108; a load center 110; and a MID 140 (microgrid interconnect device (or an island interconnect device IID)) or a relay disconnect or similar). In some embodiments, such as the embodiments described herein, the energy storage/delivery devices are rechargeable batteries (e.g., multi-C-rate collection of AC batteries, of various types of Lithium-ion based chemistries or similar) which may be referred to as batteries 120, although in other embodiments the energy storage/delivery devices may be any other suitable device for storing energy and providing the stored energy. Generally, each of the batteries 120 comprises a plurality of battery cells that are coupled in series and/or parallel, e.g., eight battery cells coupled in series and six cells coupled in parallel to each series battery cell to form a battery 120 (e.g., a battery pack).

Each power converter 102-1, 102-2 . . . 102-N is coupled to a DC power source 104-1, 104-2 . . . 104-N, respectively, in a one-to-one correspondence, although in some other embodiments multiple DC power sources may be coupled to one or more of the power converters 102 that converts DC to DC power. The power converters 102-N+1, 102-N+2 . . . 102-N+M are respectively coupled to plurality of energy storage devices/delivery devices 120-1, 120-2 . . . 120-M via BMUs 190-1, 190-2 . . . 190-M to form AC batteries 180-1, 180-2 . . . 180-M, respectively. Each of the power converters 102-1, 102-2 . . . 102-N+M comprises a corresponding controller 114-1, 114-2 . . . 114-N+M (collectively referred to as the inverter controllers 114) for controlling operation of the power converters 102-1, 102-2 . . . 102-N+M.

In some embodiments, such as the embodiment described below, the DC power sources 104 are DC power sources and the power converters 102 are bidirectional inverters such that the power converters 102-1 . . . 102-N convert DC power from the DC power sources 104 to grid-compliant AC power that is coupled to the bus 108, and the power converters 102-N+1 . . . 102-N+M convert (during energy storage device discharge) DC power from the batteries 120 to grid-compliant AC power that is coupled to the bus 108 and also convert (during energy storage device charging) AC power from the bus 108 to DC output that is stored in the batteries 120 for subsequent use. The DC power sources 104 may be any suitable DC source, such as an output from a previous power conversion stage, a battery, a renewable energy source (e.g., a solar panel or photovoltaic (PV) module, a wind turbine, a hydroelectric system, or similar renewable energy source), or the like (e.g., 12V or 24V or 48V car battery based regulated DC source), for providing DC power. In other embodiments the power converters 102 may be other types of converters (such as DC-DC converters), and the bus 108 is a DC power bus. In such embodiments, the battery can provide 60V that is sent to different DC converters to drive, for example, 5V, 9V, 12V, 15V, 20V etc., all of which can be straight DC outputs for charging one or more DC devices, e.g., mobile phones, laptops, speakers, LED lights etc. These are independent from Battery powering the Power converters for AC outputs.

The power converters 102 are coupled to the system controller 106 via the bus 108 (which also may be referred to as an AC line or a power grid, AC generator (propane, LGP, or similar, AC from windfarms, etc.). The system controller 106 generally comprises a CPU coupled to each of support circuits and a memory that comprises a system control module for controlling some operational aspects of the system 100 and/or monitoring the system 100 (e.g., issuing certain command and control instructions to one or more of the power converters 102, collecting data related to the performance of the power converters 102, and the like). The system controller 106 is capable of communicating with the power converters 102 (e.g., DC/AC power converters, DC/DC power converters, which can be housed in the same enclosure or in separate enclosures) by wireless and/or wired communication (e.g., power line communication) for providing certain operative control and/or monitoring of the power converters 102.

In some embodiments, the system controller 106 may be a gateway that receives data (e.g., performance data) from the power converters 102 and communicates (e.g., via the Internet) the data and/or other information to a remote device or system, such as a master controller (not shown). Additionally or alternatively, the gateway may receive information from a remote device or system (not shown) and may communicate the information to the power converters 102 and/or use the information to generate control commands that are issued to the power converters 102.

The power converters 102, which, as noted above, can be AC/DC power converters or DC/DC power converters) are coupled to the load center 110 via the bus 108, and the load center 110 is coupled to the power grid via the MID 140. When coupled to the power grid (e.g., a commercial grid or a larger microgrid) via the MID 140, the system 100 may be referred to as grid-connected; when disconnected from the power grid via the MID 140, the system 100 may be referred to as islanded or microgrid or off grid or similar nomenclature. The MID 140 determines when to disconnect from/connect to the power grid (e.g., the MID 140 may detect a grid fluctuation, disturbance, outage or the like) and performs the disconnection/connection. Once disconnected from the power grid, the system 100 can continue to generate power as an intentional island, without imposing safety risks on any line workers that may be working on the power grid, using the droop control techniques described herein. The MID 140 comprises a disconnect component (e.g., a disconnect relay(s)) for physically disconnecting/connecting the system 100 from/to the power grid. In some embodiments, the MID 140 may additionally comprise an autoformer for coupling the system 100 to a split-phase load that may have a misbalance in it with some neutral current (examples include US grid system like 120V/240V split single-phase systems). In certain embodiments, the system controller 106 comprises the MID 140 or a portion of the MID 140.

The power converters 102 convert the DC power from the DC power sources 104 and discharging batteries 120 to grid-compliant AC power and couple the generated output power to the load center 110 via the bus 108. The power is then distributed to one or more loads (for example to one or more appliances) and/or to the power grid (when connected to the power grid). Additionally or alternatively, the generated energy may be stored for later use, for example using batteries, heated water, hydro pumping, H₂O-to-hydrogen conversion, or the like. Generally, the system 100 is coupled to the commercial power grid, although in some embodiments the system 100 is completely separate from the commercial power grid and operates as an independent microgrid.

In some embodiments, the AC power generated by the power converters 102 is single-phase AC power. In other embodiments, the power converters 102 generate three-phase AC power.

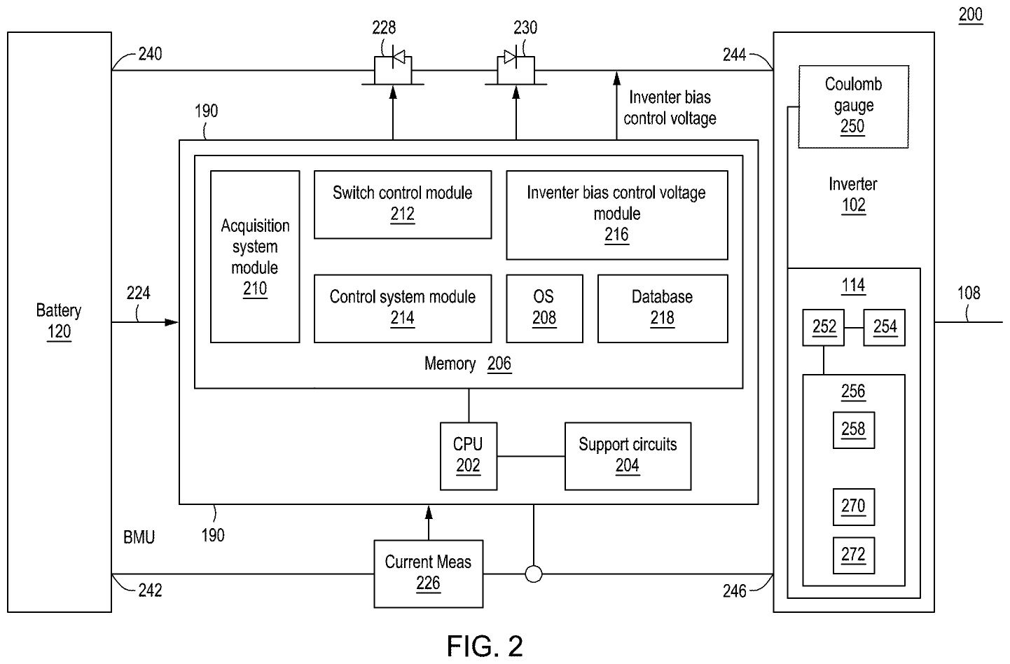

A storage system configured for use with an energy management system, such as the ENSEMBLE® energy management system available from ENPHASE®, is described herein. For example, FIG. 2 is a block diagram of an AC battery system 200 (e.g., a storage system) in accordance with one or more embodiments of the present disclosure. Alternatively, the AC battery system 200 can be a DC battery system with a corresponding battery and DC/DC power converters.

The AC battery system 200 comprises a BMU 190 coupled to a battery 120 and a power converter 102. A pair of metal-oxide-semiconductor field-effect transistors (MOSFETs) or BJT or IGBT or similar switches—switches 228 and 230—are coupled in series between a first terminal 240 of the battery 120 and a first terminal of the inverter 144 such the body diode cathode terminal of the switch 228 is coupled to the first terminal 240 of the battery 120 and the body diode cathode terminal of the switch 230 is coupled to the first terminal 244 of the power converter 102. The gate terminals of the switches 228 and 230 are coupled to the BMU 190, these switches are configured for controlling the charging to or discharging from the battery.

A second terminal 242 of the battery 120 is coupled to a second terminal 246 of the power converter 102 via a current measurement module 226 which measures the current flowing between the battery 120 and the power converter 102.

The BMU 190 is coupled to the current measurement module 226 for receiving information on the measured current, and also receives an input 224 from the battery 120 indicating the battery cell voltage and temperature. The BMU 190 is coupled to the gate terminals of each of the switches 228 and 230 for driving the switch 228 to control battery discharge and driving the switch 230 to control battery charge as described herein. The BMU 190 is also coupled across the first terminal 244 and the second terminal 246 for providing an inverter bias control voltage (which may also be referred to as a bias control voltage) to the inverter 102 as described further below.

The configuration of the body diodes of the switches 228 and 230 allows current to be blocked in one direction but not the other depending on state of each of the switches 228 and 230. When the switch 228 is active (i.e., on) while the switch 230 is inactive (i.e., off), battery discharge is enabled to allow current to flow from the battery 120 to the power converter 102 through the body diode of the switch 230. When the switch 228 is inactive while the switch 230 is active, battery charge is enabled to allow current flow from the power converter 102 to the battery 120 through the body diode of the switch 228. When both switches 228 and 230 are active, the system is in a normal mode where the battery 120 can be charged or discharged.

The BMU 190 comprises support circuits 204 and a memory 206 (e.g., non-transitory computer readable storage medium), each coupled to a CPU 202 (central processing unit). The CPU 202 may comprise one or more processors, microprocessors, microcontrollers and combinations thereof configured to execute non-transient software instructions to perform various tasks in accordance with embodiments of the present disclosure. The CPU 202 may additionally or alternatively include one or more application specific integrated circuits (ASICs). In some embodiments, the CPU 202 may be a microcontroller comprising internal memory for storing controller firmware that, when executed, provides the controller functionality described herein. The BMU 190 may be implemented using a general purpose computer that, when executing particular software, becomes a specific purpose computer for performing various embodiments of the present disclosure.

The support circuits 204 are well known circuits used to promote functionality of the CPU 202. Such circuits include, but are not limited to, a cache, power supplies, clock circuits, buses, input/output (I/O) circuits, and the like. The BMU 190 may be implemented using a general-purpose computer that, when executing particular software, becomes a specific purpose computer for performing various embodiments of the present disclosure. In one or more embodiments, the CPU 202 may be a microcontroller comprising internal memory for storing controller firmware that, when executed, provides the controller functionality described herein.

The memory 206 may comprise random access memory, read only memory, removable disk memory, flash memory, and various combinations of these types of memory. The memory 206 is sometimes referred to as main memory and may, in part, be used as cache memory or buffer memory. The memory 206 generally stores the OS 208 (operating system), if necessary, of the inverter controller 114 that can be supported by the CPU capabilities. In some embodiments, the OS 208 may be one of a number of commercially available operating systems such as, but not limited to, LINUX, Real-Time Operating System (RTOS), and the like.

The memory 206 stores non-transient processor-executable instructions and/or data that may be executed by and/or used by the CPU 202 to perform, for example, one or more methods for discharge protection, as described in greater detail below. These processor-executable instructions may comprise firmware, software, and the like, or some combination thereof. The memory 206 stores various forms of application software, such as an acquisition system module 210, a switch control module 212, a control system module 214, and an inverter bias control module 216. The memory 206 additionally stores a database 218 for storing data related to the operation of the BMU 190 and/or the present disclosure, such as one or more thresholds, equations, formulas, curves, and/or algorithms for the control techniques described herein. In various embodiments, one or more of the acquisition system module 210, the switch control module 212, the control system module 214, the inverter bias control module 216, and the database 218, or portions thereof, are implemented in software, firmware, hardware, or a combination thereof.

The acquisition system module 210 obtains the battery cell voltage and temperature information from the battery 120 via the input 224, obtains the current measurements provided by the current measurement module 226, and provides the battery cell voltage, battery cell temperature, and measured current information to the control system module 214 for use as described herein.

The switch control module 212 drives the switches 228 and 230 as determined by the control system module 214. The control system module 214 provides various battery management functions, including protection functions (e.g., overcurrent (OC) protection, overtemperature (OT) protection, and hardware fault protection), metrology functions (e.g., averaging measured battery cell voltage and battery current over, for example, 100 ms to reject 50 and 60 Hz ripple), state of charge (SOC) analysis (e.g., coulomb gauge 250 for determining current flow and utilizing the current flow in estimating the battery SOC; synchronizing estimated SOC values to battery voltages (such as setting SOC to an upper bound, such as 100%, at maximum battery voltage; setting SOC to a lower bound, such as 0%, at a minimum battery voltage); turning off SOC if the power converter 102 never drives the battery 120 to these limits; and the like), balancing (e.g., autonomously balancing the charge across all battery cells of a battery to be equal, which may be done at the end of charge, at the end of discharge, or in some embodiments both at the end of charge and the end of discharge). By establishing upper and lower estimated SOC bounds based on battery end of charge and end of discharge, respectively, and tracking the current flow and battery cell voltage (i.e., battery voltage) between these events, the BMU 190 determines the estimated SOC.

The inverter controller 114 comprises support circuits 254 and a memory 256, each coupled to a CPU 252 (central processing unit). The CPU 252 may comprise one or more processors, microprocessors, microcontrollers and combinations thereof configured to execute non-transient software instructions to perform various tasks in accordance with embodiments of the present disclosure. The CPU 252 may additionally or alternatively include one or more application specific integrated circuits (ASICs). In some embodiments, the CPU 252 may be a microcontroller comprising internal memory for storing controller firmware that, when executed, provides the controller functionality herein. The inverter controller 114 may be implemented using a general-purpose computer that, when executing particular software, becomes a specific purpose computer for performing various embodiments of the present disclosure.

The support circuits 254 are well known circuits used to promote functionality of the CPU 252. Such circuits include, but are not limited to, a cache, power supplies, clock circuits, buses, input/output (I/O) circuits, and the like. The inverter controller 114 may be implemented using a general-purpose computer that, when executing particular software, becomes a specific purpose computer for performing various embodiments of the present disclosure. In one or more embodiments, the CPU 252 may be a microcontroller comprising internal memory for storing controller firmware that, when executed, provides the controller functionality described herein.

The memory 256 may comprise random access memory, read only memory, removable disk memory, flash memory, and various combinations of these types of memory. The memory 256 is sometimes referred to as main memory and may, in part, be used as cache memory or buffer memory. The memory 256 generally stores the OS 258 (operating system), if necessary, of the inverter controller 114 that can be supported by the CPU capabilities. In some embodiments, the OS 258 may be a number of commercially available operating systems such as, but not limited to, LINUX, Real-Time Operating System (RTOS), and the like.

The memory 256 stores non-transient processor-executable instructions and/or data that may be executed by and/or used by the CPU 252. These processor-executable instructions may comprise firmware, software, and the like, or some combination thereof. The memory 256 stores various forms of application software, such as a power conversion control module 270 for controlling the bidirectional power conversion, and a battery management control module 272.

The BMU 190 communicates with the system controller 106 to perform balancing of the batteries 120 (e.g., multi-C-rate collection of AC batteries) based on a time remaining before each of the batteries are depleted of charge, to perform droop control (semi-passive) which allows the batteries to run out of charge at substantially the same time, and perform control of the batteries to charge batteries having less time remaining before depletion using batteries having more time remaining before depletion, as described in greater detail below.

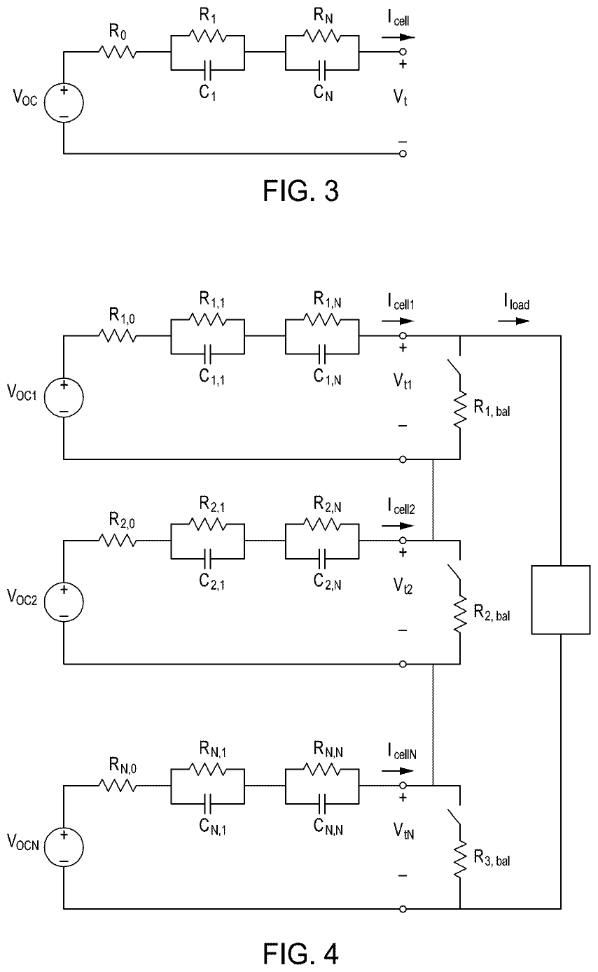

FIG. 3 is a schematic diagram of an equivalent circuit model of a single battery cell, in accordance with at least some embodiments of the present disclosure. In FIG. 3, R₀ represents an electric resistance of the wiring and battery cell interconnections (e.g., the battery cells of the battery 120) as well as the resistance of the electrolyte. R₀ results in voltage drop or rise that occurs instantly with changes in battery cell current (I_{cell}). One or more RC pairs (R₁C₁ . . . R_{N}C_{N}), each with their own time constant (Tₐᵤ=RC), are connected in series with R₀ to represent the time-dependent voltage response of the battery (e.g., the battery 120) that occurs due to charge-transfer reaction and diffusion phenomena within the battery

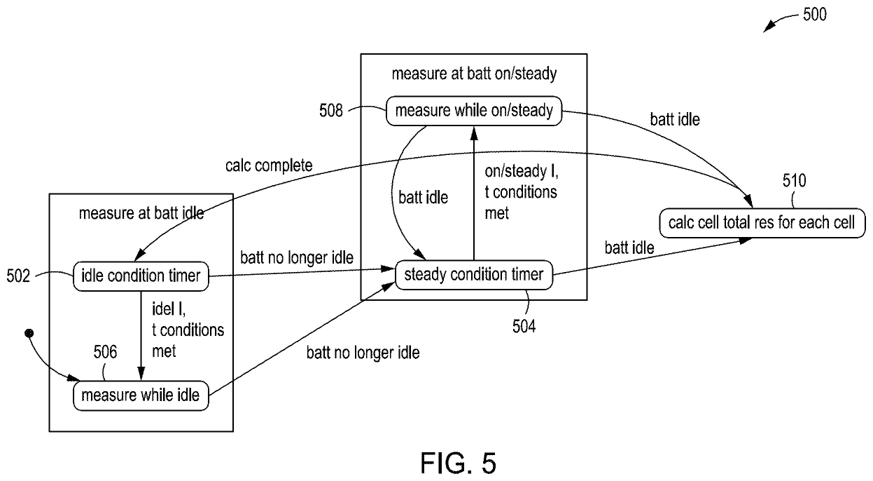

FIG. 4 is a schematic diagram of an equivalent circuit model of multiple battery cells connected in series to form a battery pack, and FIG. 5 is flowchart of an Rₜₒₜₐₗ estimation method 500, in accordance with at least some embodiments of the present disclosure. As noted above, the methods and apparatus described herein can be used for battery cell balancing, state-of-charge (SOC), state-of-health (SOH), health prediction, etc.

In FIG. 4 each battery cell has a dedicated passive balancing circuit (e.g., R_{1, bal}, R_{2, bal}, R_{3, bal}) that is used to remove energy from select battery cells to achieve balance across all battery cells. The parameters Vₜ₁, Vₜ₂ . . . V_{tN} can be measured by the traditional BMU described above. The inventors have found that estimating the Rₜₒₜₐₗ of each battery cell can be achieved directly using measurement snapshots of slow-timescale averaged measurements taken during battery idle periods (as well as during active periods). Then, V_{oc} (and therefore energy estimates using either look-up table or other simple approaches) can be estimated at any period of active battery steady state operation using ohm's law and Kirchhoff's law. The Rₜₒₜₐₗ for each battery cell is estimated using the Rₜₒₜₐₗ estimation method 500 shown in FIG. 5. For example, the Rₜₒₜₐₗ estimation can be calculated using Equations (1) and (2):

$${R}_{total} = Δ V / Δ I = ( ( {V}_{( t , idle )} - {V}_{( t , on )} ) ) / ( ( {I}_{( cell , on )} - {I}_{( cell , idle )} ) ) , \qquad ( 1 )$$

$$\begin{matrix}{I}_{( cell , i )} - {I}_{load} - Si ( {V}_{( t , i )} / {R}_{( i , bal )} ) & ∀ i ,\end{matrix} \qquad ( 2 )$$

where sᵢ∈{0,1} indicates the balancing on/off decision (on=1) for the i\hat{ }^{th} battery cell.

One or more timers of the control system module 214 of the BMU 190 can be used for measuring voltage. For example, timers (e.g., an idle condition timer 502 and a steady condition timer 504) shown in FIG. 5 ensure that the idle measurements 506 and on measurements 508 are taken after steady-state battery voltage conditions have been reached within a tolerance band, which requires only relatively short idle, and on periods in the multiple minutes' timescale. Rₜₒₜₐₗ is updated each time there is an on->idle transition and is persisted across control system shutdowns. In doing so, after just a single valid on period, idle period transition occurs, and thereafter a good estimate of Rₜₒₜₐₗ (510) will be available and is slowly updated over the life of the battery system (e.g., the AC battery system 200).

With good Rₜₒₜₐₗ measurements available, the V_{oc} of each battery cell (e.g., V_{oc1}, V_{oc2}, V_{oc3}, etc.) can be obtained at any point of active battery steady-state operation via Equation (3):

$${V}_{( oc , i )} = {V}_{( t , i )} - {I}_{( cell , i )} * {R}_{( total , i )} . \qquad ( 3 )$$

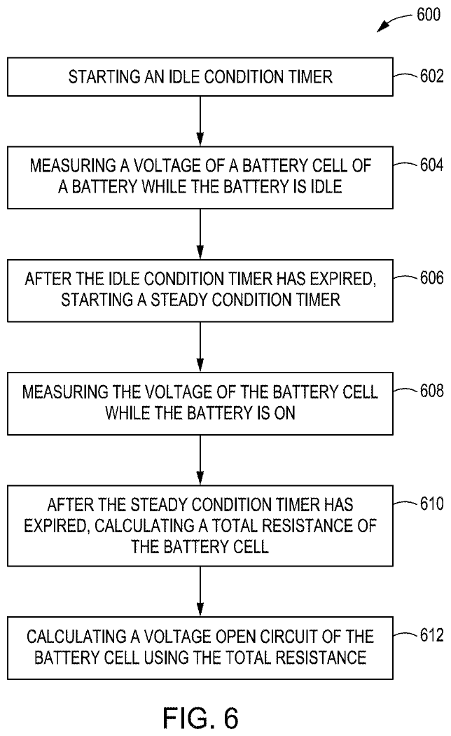

FIG. 6 is a flowchart of a method 600 for continuous battery cell balancing, in accordance with at least some embodiments of the present disclosure.

For example, under control of the control system module 214, at 602, the method 600 comprises starting an idle condition timer (e.g., idle condition timer 502) of a battery system (e.g., the AC battery system 200) for a predetermined time period. For example, the predetermined time period can be about 60 s to about 1800 s. In at least some embodiments, the predetermined time period can be about 300 s to about 600 s.

Next, at 604, the method 600 comprises measuring a voltage of a battery cell of a battery while the battery is idle. For example, one or more of the voltages Vₜ₁. Vₜ₂ . . . V_{tN} of the corresponding battery cells can be measured while the battery is idle.

Next, after the idle condition timer has expired (e.g., the battery 120 is no longer idle), at 606, the method 600 comprises starting a steady condition timer (e.g., the steady condition timer 504) of the battery system for a predetermined time period. For example, the predetermined time period can be about 1 s to about 300 s. In at least some embodiments, the predetermined time period can be about 2 s to about 20 s.

Next, at 608, the method 600 comprises measuring a voltage of the battery cell while the battery is in a steady state (e.g., is on). For example, one or more of the voltages Vₜ₁, Vₜ₂ . . . V_{tN} can be measured while the battery 120 is on.

Next, after the after the steady condition timer has expired (e.g., the battery 120 is no longer on), at 610, the method 600 comprises calculating a total resistance of the battery cell of the battery 120. For example, at 610, the method 600 comprises calculating Rₜₒₜₐₗ for each of the battery cells of the battery 120 using at least one of Equations (1) or (2).

Next, at 612, with the Rₜₒₜₐₗ measurements obtained, the method 600 comprises calculating an open circuit voltage of the battery cell using the total resistance. For example, the V_{oc} of the battery cell can be obtained via Equation (3). For example, V_{oc1}, V_{oc2}, V_{oc3} for each of the respective battery cells of the battery 120 can be obtained via Equation (3).

As noted above, once the Rₜₒₜₐₗ measurements and open circuit voltage of the battery cell are obtained, the BMU 190 can use the Rₜₒₜₐₗ measurements and open circuit voltage of the battery cell to perform at least one of battery cell balancing, state-of-charge (SOC), state-of-health (SOH), health prediction, etc. using known methods/processes.

For example, real-time V_{oc} measurements (along with I_{cell} if desired) provide the basis for good battery cell-level energy/SOC estimates that not only provide the needed inputs for effective battery cell balancing algorithms, but also give more accurate battery pack-level state of charge estimates. For example, battery manufacturers, typically, characterize their battery cells and provide a detailed look-up table of cell open circuit cell voltage vs. corresponding SOC. Having an accurate Voc measurement allows a user to make best use of this information to obtain good estimates of cell SOC. Voc estimates (versus V terminal) are critical to being able to use manufacturer Voc vs. SOC look up table information. Then, having SOC estimates for each cell in a battery pack, a cell balancing algorithm can compare SOC values and make a determination of which cell(s) need to have passive balancing circuitry turned on in order to lower the SOC of that/those cell(s) and bring it/them to a similar SOC as the other cells. Such an approach is superior to cell balancing approaches based purely on cell voltage comparisons because (1) both terminal voltage vs. SOC and open circuit voltage vs. SOC characteristics are highly non-linear and (2) using SOC, algorithms can accurately estimate how long a balancing circuit needs to be left on to bring that cell into balance with others. This is not possible when using voltage only.

Additionally, real-time Rₜₒₜₐₗ measurements give a good estimate of state of health (SOH) and can facilitate better safety by knowing if a battery cell has failed as well as inputs to failure prediction algorithms. For example, battery cells are known to have increased cell resistance as the battery cells age and a trend/rate of change in cell resistance as the battery cells approach end of life, thus, a time series of Rₜₒₜₐₗ estimates can be used to estimate the cell's remaining life. Also, cell resistance is known to increase as electrochemical degradation in the cell occurs in response to normal aging, but also in response to multiple factors including excessive heating, excessive cooling, prolonged storage at idle and/or low SOC conditions, excessive current, etc. Therefore, by monitoring Rₜₒₜₐₗ, the relative health of the battery, including failure or imminent failure, can be estimated.

While the foregoing is directed to embodiments of the present disclosure, other and further embodiments of the disclosure may be devised without departing from the basic scope thereof, and the scope thereof is determined by the claims that follow.

1. An energy storage system, comprising:
a battery management unit; and
a controller configured to start an idle condition timer, measure a voltage of a battery cell of a battery connected to the battery management unit while the battery is idle, after the idle condition timer has expired, start a steady condition timer, measure the voltage of the battery cell while the battery is on, after the steady condition timer has expired, calculate a total resistance of the battery cell, and calculate an open circuit voltage of the battery cell using the total resistance.

2. The energy storage system of claim 1, wherein the idle condition timer is on for a time period can be about 1 s to about 300 s.

3. The energy storage system of claim 1, wherein the steady condition timer is on for a time period can be about 2 s to about 20 s.

4. The energy storage system of claim 1, wherein the total resistance of the battery cell is calculated using Equations:
$${R}_{total} = Δ V / Δ I = ( ( {V}_{( t , idle )} - {V}_{( t , on )} ) ) / ( ( {I}_{( cell , on )} - {I}_{( cell , idle )} ) ) , \qquad ( 1 )$$
$$\begin{matrix}{I}_{( cell , i )} - {I}_{load} - Si ( {V}_{( t , i )} / {R}_{( i , bal )} ) & ∀ i ,\end{matrix} \qquad ( 2 )$$
where sᵢ∈{0,1} indicates a balancing on/off decision (on=1) for an i\hat{ }^{th} battery cell.

5. The energy storage system of claim 1, wherein the open circuit voltage of the battery cell is calculated using Equation:
$${V}_{( oc , i )} = {V}_{( t , i )} - {I}_{( cell , i )} * {R}_{( total , i )} . \qquad ( 3 )$$

6. A method for Rₜₒₜₐₗ estimation comprising:
starting an idle condition timer;
measuring a voltage of a battery cell of a battery while the battery is idle;
after the idle condition timer has expired, starting a steady condition timer;
measuring the voltage of the battery cell while the battery is on;
after the steady condition timer has expired, calculating a total resistance of the battery cell; and
calculating an open circuit voltage of the battery cell using the total resistance.

7. The method of claim 6, wherein the idle condition timer is on for a time period can be about 1 s to about 300 s.

8. The method of claim 6, wherein the steady condition timer is on for a time period can be about 2 s to about 20 s.

9. The method of claim 6, wherein the total resistance of the battery cell is calculated using Equations:
$${R}_{total} = Δ V / Δ I = ( ( {V}_{( t , idle )} - {V}_{( t , on )} ) ) / ( ( {I}_{( cell , on )} - {I}_{( cell , idle )} ) ) , \qquad ( 1 )$$
$$\begin{matrix}{I}_{( cell , i )} - {I}_{load} - Si ( {V}_{( t , i )} / {R}_{( i , bal )} ) & ∀ i ,\end{matrix} \qquad ( 2 )$$
where sᵢ∈{0,1} indicates a balancing on/off decision (on=1) for an i\hat{ }^{th} battery cell.

10. The method of claim 6, wherein the open circuit voltage of the battery cell is calculated using Equation:
$${V}_{( oc , i )} = {V}_{( t , i )} - {I}_{( cell , i )} * {R}_{( total , i )} . \qquad ( 3 )$$

11. A non-transitory computer readable storage medium having instructions stored thereon that when executed by a processor perform a method for Rₜₒₜₐₗ estimation, comprising:
starting an idle condition timer;
measuring a voltage of a battery cell of a battery while the battery is idle;
after the idle condition timer has expired, starting a steady condition timer;
measuring the voltage of the battery cell while the battery is on;
after the steady condition timer has expired, calculating a total resistance of the battery cell; and
calculating an open circuit voltage of the battery cell using the total resistance.

12. The non-transitory computer readable storage medium of claim 11, wherein the idle condition timer is on for a time period can be about 1 s to about 300 s.

13. The non-transitory computer readable storage medium of claim 11, wherein the steady condition timer is on for a time period can be about 2 s to about 20 s.

14. The non-transitory computer readable storage medium of claim 11, wherein the total resistance of the battery cell is calculated using Equations:
$${R}_{total} = Δ V / Δ I = ( ( {V}_{( t , idle )} - {V}_{( t , on )} ) ) / ( ( {I}_{( cell , on )} - {I}_{( cell , idle )} ) ) , \qquad ( 1 )$$
$$\begin{matrix}{I}_{( cell , i )} - {I}_{load} - Si ( {V}_{( t , i )} / {R}_{( i , bal )} ) & ∀ i ,\end{matrix} \qquad ( 2 )$$
where sᵢ∈{0,1} indicates a balancing on/off decision (on=1) for an i\hat{ }^{th} battery cell.

15. The non-transitory computer readable storage medium of claim 11, wherein the open circuit voltage of the battery cell is calculated using Equation:
$${V}_{( oc , i )} = {V}_{( t , i )} - {I}_{( cell , i )} * {R}_{( total , i )} . \qquad ( 3 )$$
